(19) United States
(12) Patent Application Publication
(10) Pub. No.: US 2015/0325437 A1
(43) Pub. Date: Nov. 12, 2015

(54) METHOD FOR MANUFACTURING COMPOUND SEMICONDUCTOR SENSITIVE FILM BASED ON DISPLACEMENT REACTION-THERMAL OXIDATION METHOD

(71) Applicant: Institute of Microelectronics, Chinese Academy of Sciences, Beijing (CN)

(72) Inventors: Dongmei LI, Beijing (CN); Xin CHEN, Beijing (CN); Shengfa LIANG, Beijing (CN); Shuang ZHAN, Beijing (CN); Peiwen ZHANG, Beijing (CN); Changqing XIE, Beijing (CN); Ming LIU, Beijing (CN)

(21) Appl. No.: 14/801,547

(22) Filed: Jul. 16, 2015

Related U.S. Application Data
(63) Continuation of application No. PCT/CN2013/070590, filed on Jan. 17, 2013.

(51) Int. Cl. H01L 21/02; H01L 21/388

(52) U.S. Cl. CPC H01L 21/02554; H01L 21/02381; H01L 21/0242; H01L 21/02617; H01L 21/388

(57) ABSTRACT

The present disclosure provides a method for preparing compound semiconductor sensitive film based on a displacement reaction-thermal oxidation method, the method comprising: growing a layer of Zn on a high temperature-resistant substrate; submerging the substrate on which the layer of Zn has been grown into ionic solution of soluble salt of Cu, such that Cu ions in the solution are displaced so as to separate Cu nano-particles out on a surface of the layer of Zn; and performing a thermal oxidation process on the layer of Zn to whose surface Cu nano-particles are adhered, such that the Cu nano-particles are oxidized into CuO nano-particles, so as to obtain a ZnO gas sensitive film that is doped with CuO nano-particles. The above preparing method has the following advantages: good filming quality, simplified preparation process, low cost and easy to control.

### CROSS-REFERENCE TO RELATED APPLICATION(S)

This application is a U.S. National Phase Application of International Application No. PCT/CN2013/070590, filed on Jan. 17, 2013, entitled “METHOD FOR PREPARING COMPOUND SEMICONDUCTOR SENSITIVE FILM BASED ON DISPLACEMENT REACTION-THERMAL OXIDATION METHOD,” which is incorporated herein by reference in their entirety.

### TECHNICAL FIELD

The disclosure relates to the field of compound semiconductor sensitive film preparation, and particularly to a method for preparing compound semiconductor sensitive film based on a displacement reaction-thermal oxidation method, such that CuO-doped ZnO sensitive films that are applicable to sensors and catalysis may be prepared.

### BACKGROUND

In environment monitoring, industrial production, and medical caring and some other domains, it is very important to monitor and detect CO and H₂ due to respective toxic and hazardous nature of such gases. Sensors that can detect CO and H₂ comprise electro-chemical sensors, infrared sensors, catalytic combustion gas sensors and semiconductor gas sensors, etc., among which, the electro-chemical sensors are toxic prone, the infrared sensors are expensive and inconvenient for carrying, and the catalytic combustion gas sensors are poor in the sense of selectivity. In comparison, the semiconductor gas sensors induce variation of electrical characteristics by means of the semiconductors' absorption and reaction with the gas, and further implement the function of identifying and detecting concentration by detecting the variation. There are various kinds of semiconductors and their selectivity and sensitivity may be enhanced by doping or other approaches. Therefore, the semiconductor gas sensors have a promising prospect in the domain of gas detection.

Since the principle of detecting sensitive objects by semiconductor gas sensors utilizes reaction between a sensitive film and reactant, the selection and preparation of the sensitive film is essential for the performance of the semiconductor gas sensors, and is one of the most critical techniques for the semiconductor gas sensors.

ZnO is well-developed semiconductor sensitive material, which has good performance in detecting CO, H₂ or other gases. Therefore, there have been widespread researches on sensitive films constituted of ZnO. ZnO sensitive films that are reasonably doped will greatly improve the sensitivity and stability when detecting CO and H₂ and the like by the semiconductor gas sensors. However, currently, a gas sensor with doped ZnO sensitive film generally transfers doped ZnO compound onto a sensor substrate via solution reaction, which will lead to poor adhesion of its film, and sometimes organic adhesive mixing is required in the process. ZnO that is doped by other approaches such as magnetic controlled scattering and the like has got respective disadvantages, such as uncontrollable distribution and status of the doping particles, and it is difficult to control the size of the doping particles.

Therefore, it is positive for researches and industrial production in the semiconductor gas sensor domain to find a new filming method for producing ZnO sensitive films with good adhesion and controllable doping.

### SUMMARY

### Technical Problem

Based thereon, the object of the present disclosure is to provide a method for preparing compound semiconductor sensitive film based on a displacement reaction-thermal oxidation method, so as to prepare ZnO sensitive films that are doped with CuO nano-particles.

### Technical Solution

To realize the above object, the present disclosure provides a method for preparing compound semiconductor sensitive film based on a displacement reaction-thermal oxidation method, the method comprising: growing a layer of Zn on a high temperature-resistant substrate; submerging the substrate on which the layer of Zn has been grown into ionic solution of soluble salt of Cu, such that Cu ions in the solution are displaced so as to separate Cu nano-particles out on a surface of the layer of Zn; and performing a thermal oxidation process on the layer of Zn to whose surface Cu nano-particles are adhered, such that the Cu nano-particles are oxidized into CuO nano-particles, so as to obtain a ZnO gas sensitive film that is doped with CuO nano-particles.

In the above solution, the step of growing a layer of Zn on a high temperature-resistant substrate further comprises: growing the layer of Zn on the high temperature-resistant substrate by using an electron beam evaporation method or a magnetic controlled scattering method.

In the above solution, the high temperature-resistant substrate is made of one of silicon, quartz, aluminum oxide and ceramics. A thickness of the layer of Zn is between 10 nm and 5000 nm.

In the above solution, in the step of submerging the substrate on which the layer of Zn has been grown into ionic solution of soluble salt of Cu, the ionic solution of soluble salt of Cu is Cu(NO₃)₂, CuCl₂, CuSO₄, Cu(NO₃)₂ or Cu(CH₃COO)₂. The molar concentration of the ionic solution of soluble salt of Cu is 10⁻⁵ M-10⁻M. The submerging duration is between 30 seconds to 5 hours.

In the above solution, in the step of performing a thermal oxidation process on the layer of Zn to whose surface Cu nano-particles are adhered, the thermal oxidation process satisfies the following conditions: the temperature of the oxidation furnace is 400° C.-950° C.; and the duration is between 3 hours to 12 hours.

Beneficial Effects

The present disclosure provides a method for preparing compound semiconductor sensitive film based on a displacement reaction-thermal oxidation method. In this method, a layer of Zn is first grown on a high temperature-resistant substrate. Next, the substrate on which the layer of Zn has been grown is submerged into ionic solution of soluble salt of Cu, such that Cu atoms are directly reduced on the layer of Zn by via displacement reaction, so as to separate Cu nano-particles out on a surface of the layer of Zn. Then, a CuO-doped ZnO sensitive film is formed by a thermal oxidation process. The displacement may be performed under normal temperature or in a water bath environment. Such a process is easy to control, and has low reaction temperature and low power consumption. Moreover, the solution of the present disclosure prepare the ZnO sensitive film with in-situ doped CuO directly on the substrate, so that drying centrifugation that is required in solution reaction nano-material preparation methods such as sol-gel and water-heat reaction methods is not needed any more and the prepared nano-material needs not to be transferred onto the substrate. Additionally, the solution of the present disclosure has got other advantages for future application, such as better controllability, suitability for bulk production, higher efficiency than normal solution reaction, low cost without expensive equipment, good adhesion and controllable doping.

### BRIEF DESCRIPTION OF THE DRAWINGS

The present disclosure is described in detail herein with reference to drawings and embodiments, wherein:

FIG. 1 is a flow chart of the method for preparing compound semiconductor sensitive film based on a displacement reaction-thermal oxidation method in accordance with an embodiment of the present disclosure.

FIGS. 2-1 to 2-3 are flow charts of the processes for preparing compound semiconductor sensitive film based on a displacement reaction-thermal oxidation method in accordance with an embodiment of the present disclosure.

### DETAILED DESCRIPTION

To better understand the object, technical solution and advantages of the present disclosure, the present disclosure is illustrated in detail as below by means of embodiments and with references to the drawings.

First, the principle for the displacement reaction-thermal oxidation method is introduced. The displacement reaction is one kind of reaction in which an elementary substance and a chemical compound reacts to generate another elementary substance and another chemical compound. In the present disclosure, metal Zn which has a stronger metal activity can displace metal Cu which has a weaker metal activity, such that Cu nano-particles can be adhered to the Zn surface, and CuO-doped ZnO sensitive film can be further obtained after a thermal oxidation process.

Based on the above principle, in this method for preparing compound semiconductor sensitive film based on a displacement reaction-thermal oxidation method as provided in the disclosure, a layer of Zn is first deposited on a high temperature-resistant substrate. Next, the substrate on which the layer of Zn has been deposited is submerged into ionic solution of soluble salt of Cu, such that Cu atoms are directly reduced on the layer of Zn by displacement reaction, so as to separate Cu nano-particles out on a surface of the layer of Zn. Then, a CuO-doped ZnO sensitive film is formed by a thermal oxidation process.

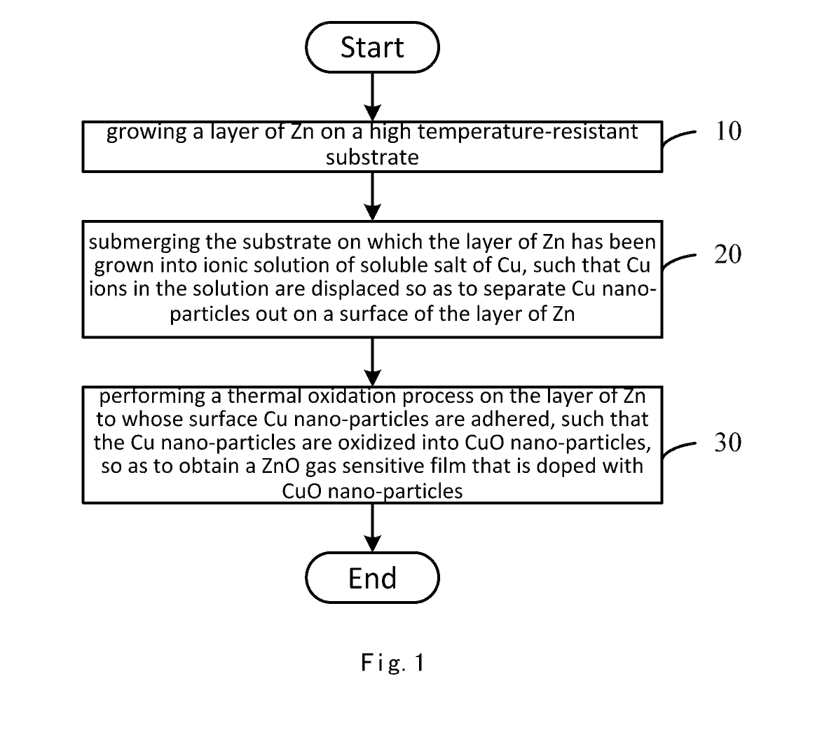

FIG. 1 is a flow chart of the method for preparing compound semiconductor sensitive film based on a displacement reaction-thermal oxidation method in accordance with an embodiment of the present disclosure, wherein the method comprises the following steps.

Step 10: growing a layer of Zn on a high temperature-resistant substrate.

In this step, the layer of Zn is grown on the high temperature-resistant substrate by using an electron beam evaporation method or a magnetic controlled scattering method. The high temperature-resistant substrate is made of silicon, quartz, aluminum oxide or ceramics. A thickness of the layer of Zn is between 10 nm and 5000 nm. Preferably, the thickness of the layer of Zn may be 10 nm, 80 nm, 800 nm, 2500 nm, 3500 nm or 5000 nm.

Step 20: submerging the substrate on which the layer of Zn has been grown into ionic solution of soluble salt of Cu, such that Cu ions in the solution are displaced so as to separate Cu nano-particles out on a surface of the layer of Zn.

In this step, the ionic solution of soluble salt of Cu is Cu(NO₃)₂, CuCl₂, CuSO₄, Cu(NO₃)₂ or Cu(CH₃COO)₂ and the like. The temperature of the ionic solution of soluble salt of Cu is 0° C.-100° C. The molar concentration of the ionic solution of soluble salt of Cu is 10⁻⁵ M-10⁻¹M. The submerging duration is between 30 seconds to 5 hours. Since Zn has better reduction than Cu, then Cu ions in the solution are displaced so as to separate Cu nano-particles out on a surface of the layer of Zn. The size of Cu nano-particles may be controlled based on concentration, temperature and submerging duration of the solution. For example, at given certain temperature and submerging duration, the higher the concentration of the solution is, the larger the number of the Cu nano-particles separated out on the surface of the layer of Zn would be and the larger their sizes would be; at given certain concentration and submerging duration, the higher the temperature is, the smaller the sizes of the Cu nano-particles separated out on the surface of the layer of Zn would be; at given certain temperature and submerging duration, the higher the concentration of the solution is, the larger the number of the Cu nano-particles separated out on the surface of the layer of Zn would be. Preferably, for a substrate on whose surface a layer of Zn with a thickness of 80 nm is grown, in embodiment A of the disclosure, the temperature of the ionic solution of soluble salt of Cu is 0° C. , the molar concentration is 10⁻⁵M, and the submerging duration is 5 hours; in embodiment B of the disclosure, the temperature of the ionic solution of soluble salt of Cu is 100° C., the molar concentration is 10⁻¹M, and the submerging duration is 30 seconds; in embodiment C of the disclosure, the temperature of the ionic solution of soluble salt of Cu is 40° C., the molar concentration is 10⁻⁴M, and the submerging duration is 4 hours; in embodiment D of the disclosure, the temperature of the ionic solution of soluble salt of Cu is 60° C., the molar concentration is 10⁻²M, and the submerging duration is 2 hours.

Step 30: performing a thermal oxidation process on the layer of Zn to whose surface Cu nano-particles are adhered, such that the Cu nano-particles are oxidized into CuO nano-particles, so as to obtain a ZnO gas sensitive film that is doped with CuO nano-particles.

In this step, the thermal oxidation process satisfies the following conditions: the temperature of the oxidation furnace is 400° C.-950° C.; and the duration is between 3 hours to 12 hours. Preferably, in the embodiment A of the disclosure, the temperature of the oxidation furnace is 400° C.; and the duration is 12 hours; in the embodiment B of the disclosure, the temperature of the oxidation furnace is 950° C.; and the duration is 3 hours; in the embodiment C of the disclosure, the temperature of the oxidation furnace is 700° C.; and the duration is 5 hours; in the embodiment D of the disclosure, the temperature of the oxidation furnace is 550° C.; and the duration is 6 hours.

Based on the flow chart of the method as shown in FIG. 1, FIGS. 2-1 to 2-3 show flow charts of the processes for preparing compound semiconductor sensitive film based on a displacement reaction-thermal oxidation method in accordance with an embodiment of the present disclosure.

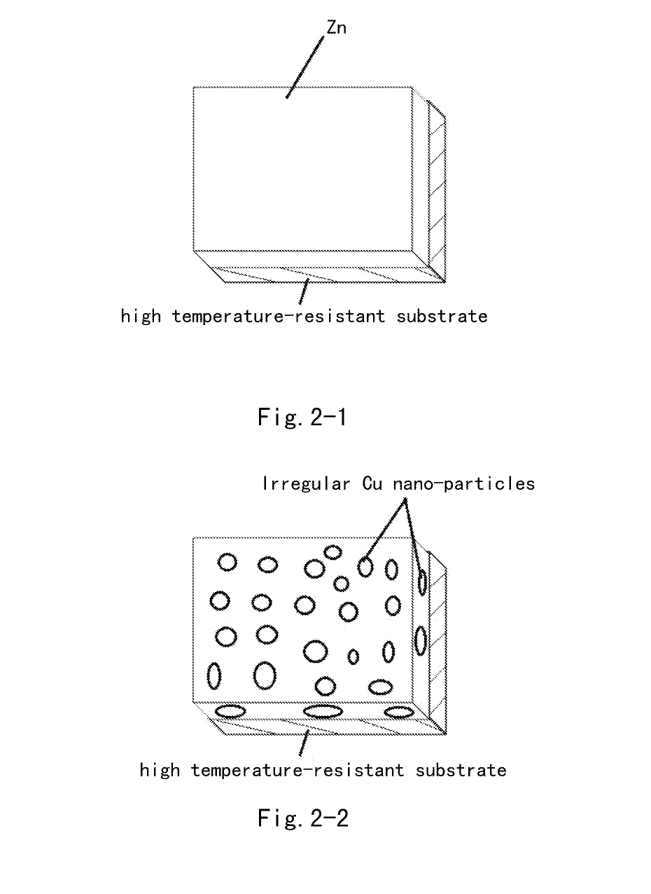

FIG. 2-1 is a diagram in which a layer of Zn is already grown on the SiO₂ substrate using the electron evaporation approach. The growing process satisfies the following conditions: the temperature is 300° C., vacuum degree is 1×10⁻⁶ torr, and the evaporation rate is 0.1 nm/s; and the thickness of Zn is 80 nm.

FIG. 2-2 is a diagram in which the substrate on which Zn has been grown is submerged into solution of Cu(NO₃)₂, CuCl₂, CuSO₄, Cu(NO₃)₂ or Cu(CH₃COO)₂ with concentration of 10⁻¹-10⁻⁶M and temperature of 0-100° C. for a duration between 30 seconds and 5 hours, and Cu nano-particles are already separated out on the surface of the layer of Zn. Preferably, a substrate with Zn having a thickness of 80 nm is submerged into a solution of Cu(NO₃)₂ with concentration of 10⁻³M and temperature of 90° C. for 5 minutes so as to separate out Cu nano-particles on the surface of the layer of Zn.

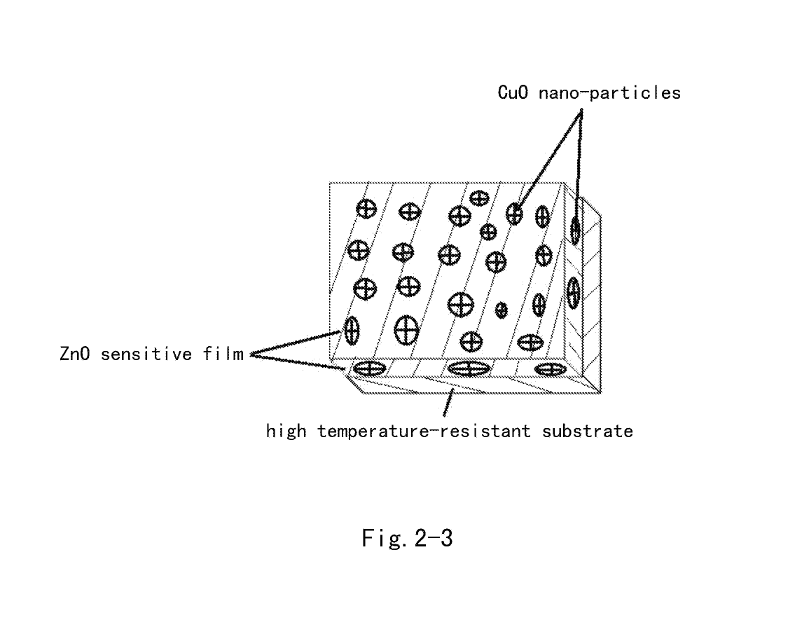

FIG. 2-3 is a diagram in which ZnO sensitive film with doped CuO nano-particles are obtained after a thermal oxidation process. The oxidation temperature is 400-950° C., and the oxidation duration is 3-12 hours. Preferably, the temperature is 550° C., and the oxidation duration is 6 hours.

The present disclosure grows Cu nano-particles on the surface of the layer of Zn by utilizing the principle of the displacement reaction, and obtains a CuO-doped ZnO sensitive film by a thermal oxidation method, wherein the obtained film may be used in various fields such as sensors and catalysis. In the preparation process for the sensitive film, a layer of Zn is first grown by using electron evaporation or magnetic controlled scattering. Next, the layer of Zn is submerged into Cu (NO₃) ₂ or other ionic solution of soluble salt of Cu with certain concentration for certain duration of time, so as to separate Cu-particles out on a surface of the layer of Zn via the reduction of Zn, since Zn has a stronger metal activity than Cu. The sizes of the Cu particles may be controlled based on concentration, temperature and submerging duration of the solution. Then, a ZnO sensitive film with doped CuO nano-particles is obtained after a thermal oxidation process. The sensitivity and stability of the doped sensitive film with respect to CO and H₂ are greatly improved. The preparation method has the following advantages: good filming quality, simplified preparation process, low cost and easy to control.

The above embodiments further illustrate the object, technical solution and beneficial effects of the present disclosure. It should be appreciated that, the above embodiments are only exemplary and do not serve to limit the present disclosure. Any modifications, substitutions, or improvements should be contained in the scope of the present disclosure as long as they do not depart from the spirits and principles of the present disclosure.

What is claimed is:

1. A method for preparing compound semiconductor sensitive film based on a displacement reaction-thermal oxidation method, wherein the method comprising:
growing a layer of Zn on a high temperature-resistant substrate;
submerging the substrate on which the layer of Zn has been grown into ionic solution of soluble salt of Cu, such that Cu ions in the solution are displaced so as to separate Cu nano-particles out on a surface of the layer of Zn; and
performing a thermal oxidation process on the layer of Zn to whose surface Cu nano-particles are adhered, such that the Cu nano-particles are oxidized into CuO nano-particles, so as to obtain a ZnO gas sensitive film that is doped with CuO nano-particles.

2. A method according to claim 1, wherein the step of growing a layer of Zn on a high temperature-resistant substrate further comprising:
growing the layer of Zn on the high temperature-resistant substrate by using an electron beam evaporation method or a magnetic controlled scattering method.

3. A method according to claim 1, wherein the high temperature-resistant substrate is made of silicon, quartz, aluminum oxide or ceramics.

4. A method according to claim 1, wherein a thickness of the layer of Zn is between 10 nm and 5000 nm.

5. A method according to claim 1, wherein in the step of submerging the substrate on which the layer of Zn has been grown into ionic solution of soluble salt of Cu, the ionic solution of soluble salt of Cu is Cu(NO₃)₂, CuCl₂, CuSO₄, Cu(NO₃)₂ or Cu(CH₃COO)₂.

6. A method according to claim 1, wherein in the step of submerging the substrate on which the layer of Zn has been grown into ionic solution of soluble salt of Cu, the molar concentration of the ionic solution of soluble salt of Cu is 10⁻⁵ M-10⁻¹M.

7. A method according to claim 1, wherein in the step of submerging the substrate on which the layer of Zn has been grown into ionic solution of soluble salt of Cu, the submerging duration is between 30 seconds to 5 hours.

8. A method according to claim 1, wherein in the step of performing a thermal oxidation process on the layer of Zn to whose surface Cu nano-particles are adhered, the thermal oxidation process satisfies the following conditions:
the temperature of the oxidation furnace is 400° C.-950° C.; and
the duration is between 3 hours to 12 hours.

9. A method according to claim 2, wherein the high temperature-resistant substrate is made of silicon, quartz, aluminum oxide or ceramics.

10. A method according to claim 2, wherein a thickness of the layer of Zn is between 10 nm and 5000 nm.
